(19) United States
(12) Patent Application Publication
(10) Pub. No.: US 2007/0152727 A1
(43) Pub. Date: Jul. 5, 2007

(54) Clock signal generating apparatus and clock signal receiving apparatus

(75) Inventors: Seok-Jin Lee, Daejeon-city (KR); Seung-Kwon Cho, Guri-city (KR); Young-Il Kim, Daejeon-city (KR)

Correspondence Address: THE FARRELL LAW FIRM, P.C., 333 EARLE OVINGTON BOULEVARD, SUITE 701, UNIONDALE, NY, 11553, US

(73) Assignees: Samsung Electronics Co., Ltd., Suwon-si (KR); Electronics and Telecommunications Research Institute, Daejeon (KR); KT Corporation, Seongnam-city (KR); SK TELECOM CO., LTD., Seoul (KR); HANARO TELECOM., INC., Seoul (KR)

(21) Appl. No.: 11/636,938

(22) Filed: Dec. 11, 2006

(30) Foreign Application Priority Data
Dec. 10, 2005 (KR) 2005-0121366

(51) Int. Cl. G06F 1/04; H03K 3/00

(52) U.S. Cl. 327/291

(57) ABSTRACT

A clock signal generating apparatus including a clock generator, a distributor, a plurality of delay units, and generates a clock signal for synchronized driving of a system having a plurality of clock receiving apparatuses. The clock signal generator generates a clock signal for driving the system by using an external clock signal and a feedback clock signal. The distributor distributes the clock signal output to generate a plurality of distributed clock signals and outputs the plurality of distributed clock signals to the plurality of clock receiving apparatuses through a plurality of signal transmission paths. The plurality of delay units are respectively located on the plurality of signal transmission paths, control phases of the plurality of distributed clock signals to generate a plurality of phase-controlled clock signals, and transmit the plurality of phase-controlled clock signals to the plurality of clock receiving apparatuses.

### PRIORITY

This application claims priority to Korean Patent Application No. 10-2005-0121366 filed in the Korean Intellectual Property Office on Dec. 10, 2005, the contents of which are incorporated herein by reference.

### BACKGROUND OF THE INVENTION

1. Field of the Invention

The present invention relates to a clock signal generating apparatus and a clock signal receiving apparatus that have an advantage of eliminating clock signal deviation.

2. Description of the Related Art

Recently, various parts that configure an electronic device have been improved in performance, and accordingly, a signal transmission speed must be guaranteed by eliminating deviation of a clock signal used for driving each part of the device through signal transmission synchronization between each part of the device to thereby improve electronic device performance. Therefore, signal synchronization for elimination of clock deviation in signal transmission between a board and a plurality of chips, as well as between a peripheral device and the chips, becomes a very important factor that can affect overall system performance.

An electronic circuit is usually driven in synchronization with a clock signal, and accordingly, an I/O interface-based electronic device or electronic part that transmits data in synchronization with a clock signal frequency needs to perform accurate time synchronization between the clock signal and data, since a load of the bus is increased and a frequency speed of the clock signal becomes fast. That is, the data must be synchronized to an edge or the center of the clock signal.

Synchronization of the data to the edge or center of the clock signal relates to a method for performing high-speed signal transmission between a plurality of large scale integrated (LSI) circuits, between circuit blocks, and between boards. In order to precisely synchronize the data to the edge or center of the clock signal, a binary digital signal (i.e., clock) for synchronization of each element involved in the data transmission must be inverse-compensated with a time taken for loading the data to the bus.

Particularly, unlike clock signal transmission/receiving of a low-speed device, clock signal transmission/receiving of a high-speed device causes signal transmission delay due to a path length difference between each of clock receiving ends and the clock signal generator, and due to a timing skew caused by the signal transmission delay. Therefore, the delay time must be compensated.

In addition, noise inflow during the high-speed clock signal transmission causes degradation of signal stability. That is, when a clock waveform of a clock transmitted from the clock signal generator is received by a receiving side, the clock waveform is distorted due to noise inflow during the signal transmission as shown in FIG. 1. Accordingly, when determining a level of the received clock signal, a result value may vary depending on a sampling point, thereby causing deterioration of system stability. As a result, click jitter or glitch is generated as shown in FIG. 2. In FIG, 2, a dotted-line waveform denotes a waveform of a signal without distortion and a solid-lined waveform denotes a waveform of a signal with distortion.

Conventionally, low voltage differential signaling (LVDS) is used to eliminate the distortion from the received signal. However, two signal lines are required for transmission of one signal and the clock signal generator must be able to generate a precise inverse signal. Otherwise, clock jitter occurs due to noise, thereby causing system instability. Therefore, a method for efficiently eliminating clock deviation between a plurality of clock receiving ends, each receiving and using a system clock, is required in a high-speed device.

### SUMMARY OF THE INVENTION

The present invention has been made in an effort to provide a clock generating apparatus and a clock signal receiving apparatus having the advantage of compensating time delay due to a transmission path difference between a plurality of clock receiving apparatuses to eliminate clock deviation.

A clock signal generating apparatus according to the present invention provides a clock signal to synchronize driving of a system having a plurality of clock signal receiving apparatuses. The clock generating apparatus includes a clock generator, a distributor, and a plurality of delay units. The clock signal generator generates a clock signal for driving the system by using an external clock signal and a feedback clock signal. The distributor distributes the clock signal to generate a plurality of distributed clock signals and outputs the plurality of distributed clock signals to the plurality of clock signal receiving apparatuses through a plurality of signal transmission paths. The plurality of delay units are respectively located on the plurality of signal transmission paths, control phases of the plurality of distributed clock signals to generate a plurality of phase-controlled clock signals, and transmit the plurality of phase-controlled clock signals to the plurality of clock receiving apparatuses. In addition, one of the plurality of delay units feeds one of the phase-controlled clock signals back to the clock signal generator.

A clock signal receiving apparatus according to the present invention includes an amplifier, a first input voltage adjusting unit, a second input adjusting unit, and a feedback unit. The amplifier generates an amplified signal based on an input signal of a first input end and an input signal of a second input end, and outputs the amplified signal to an output end. The first input voltage adjusting unit adjusts a voltage level of a clock signal transmitted from a clock signal generating apparatus, and provides the adjusted clock signal to the first input end. The second input voltage adjusting unit provides a source voltage divided by a voltage divider to the second input end. The feedback unit is connected between the output end and the second input end, and eliminates noise.

### BRIEF DESCRIPTION OF THE DRAWINGS

The above and other objects, features and advantages of the present invention will become more readily apparent from the following detailed description, taken in conjunction with the accompanying drawings, in which:

FIG. 1 is a waveform diagram transmitted to a conventional clock receiving apparatus;

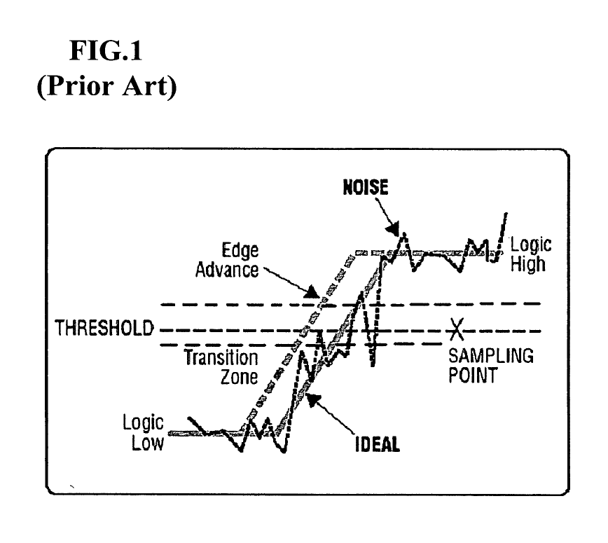

FIG. 2 shows clock signal distortion due to clock jitter;

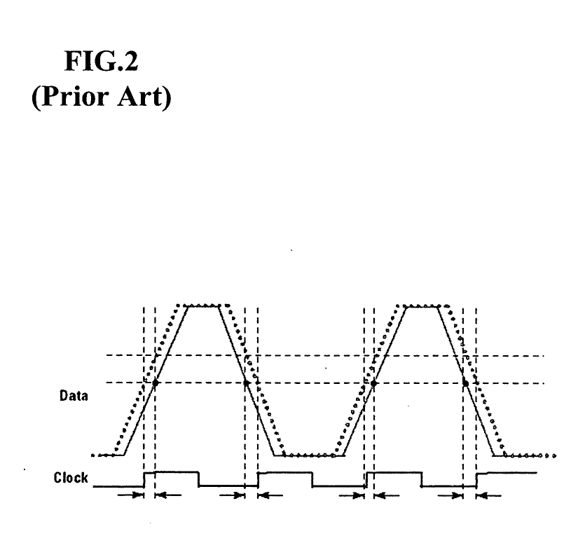

FIG. 3 is a block diagram of a clock generating apparatus according to an exemplary embodiment of the present invention;

FIG. 4 is a clock signal waveform diagram according to the exemplary embodiment of the present invention;

FIG. 5 shows a clock signal receiving apparatus according to the exemplary embodiment of the present invention; and

FIG. 6 shows a clock signal having its duty ratio adjusted by using a D-flipflop.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

A clock transmitting apparatus providing clock synchronization and a clock signal receiving apparatus according to an exemplary embodiment of the present invention will now be described in more detail with reference to the accompanying drawings.

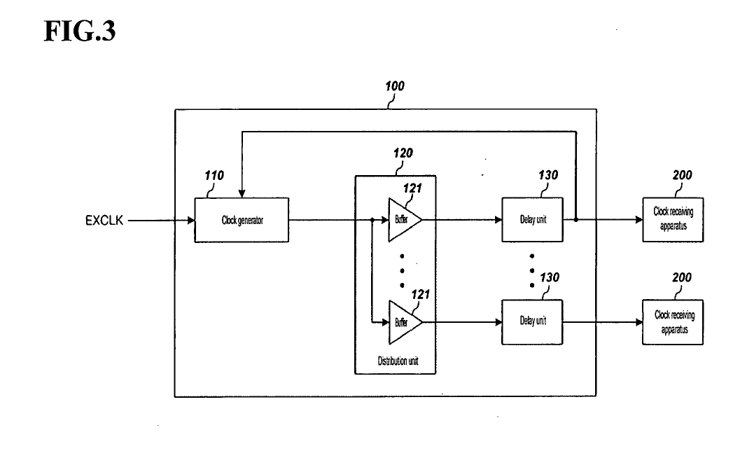

FIG. 3 is a block diagram of a click transmitting apparatus according to the exemplary embodiment of the present invention.

As shown in FIG. 3, a clock signal generating apparatus 100 includes a clock signal generator 110, a distribution unit 120, and a plurality of delay units 130, and clock signals output from the respective delay units are transmitted to a plurality of clock receiving apparatuses 200. In addition, the distribution unit 120 includes a plurality of zero delay buffers 121.

The clock signal generator 110 generates a clock signal for driving a system on which the plurality of clock receiving apparatuses are installed by using an external clock signal (EXCLK) and a feedback clock signal inputted from the delay unit 130. The external clock signal (EXCLK) is received from an external clock signal generator, an electronic part, or a circuit connected to the clock signal generator 110. The clock signal generator 110 generates a new clock signal by using an oscillation output phase difference between the external clock signal EXCLK and the feedback clock signal. In this case, the clock signal generator 110 can be provided as a phase locked loop (PLL).

The distribution unit 120 distributes the clock signal generated by the clock signal generator 110 so as to transmit the distributed clock signals to the plurality clock signal receiving apparatuses 200, and transmits each of the distributed clock signals through each signal transmission path directly connected with each of the respective clock receiving apparatuses 200. Herein, the distribution unit 120 may include the plurality of zero delay buffers 121 for the clock signal distribution.

The delay units 130 are respectively located on signal transmission paths between the distribution unit 120 and the plurality of clock receiving apparatuses 200, and control a clock signal phase to maintain a phase of each clock signal received by each of the plurality of clock receiving apparatuses 200 to be equal to each other at a specific point to thereby g synchronization. In this case, the delay unit 130 can control a phase of each clock signal output from the distribution unit 120 with a delay time that is inversely proportional to the length of each signal transmission path between the clock signal generator 100 and the clock signal receiving apparatus 200. That is, when the length of the signal transmission path between the clock signal generator 100 and the clock signal receiving apparatus 200 is short, the delay time is increased so as to solicit phase synchronization with a clock signal for another clock signal receiving apparatus 200 that has a long transmission signal path.

In addition, a predetermined delay unit 130 among the plurality of delay units 130 sends a phase-controlled clock signal to the clock signal generator 110 as feedback and provides the phase-controlled clock signal to the clock signal generator 110 as an input signal. In this case, the predetermined delay unit 130 can be configured to include at least one delay element, and the at least one delay element can be replaced with any element commonly used for time delay.

The clock signal generator 100 according to the exemplary embodiment of the present invention can reduce jitter generation by using a phase locked loop (LLP) having a low frequency transmission characteristic. In addition, the distribution unit 120 can buffer an input clock signal to generate a plurality of clock signals, respectively having the same phase with no delay, without being influenced by a load effect. The clock signal reduces skew between signals so that synchronization accuracy between circuits can be guaranteed. In addition, since an impedance matching load is eliminated, design of a system having various clock receiving apparatuses is facilitated, each receiving a clock signal for driving the system.

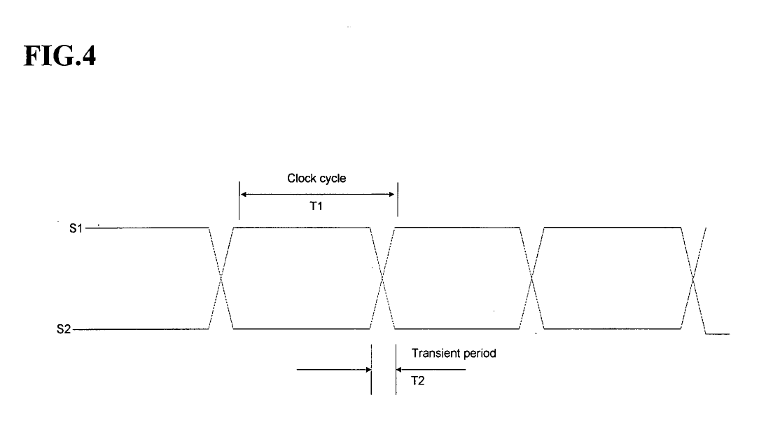

FIG. 4 is a waveform diagram of a clock signal output from the clock signal generator according to the exemplary embodiment of the present invention. In FIG. 4, S1 denotes a clock signal, S2 denotes an inverse signal of S1, T1 denotes a clock cycle, and T2 denotes a period, other than signal parts that determine “0” and “1”, that is, a transient period during which a voltage level is changed from “0” to “1” or from “1” to “0”.

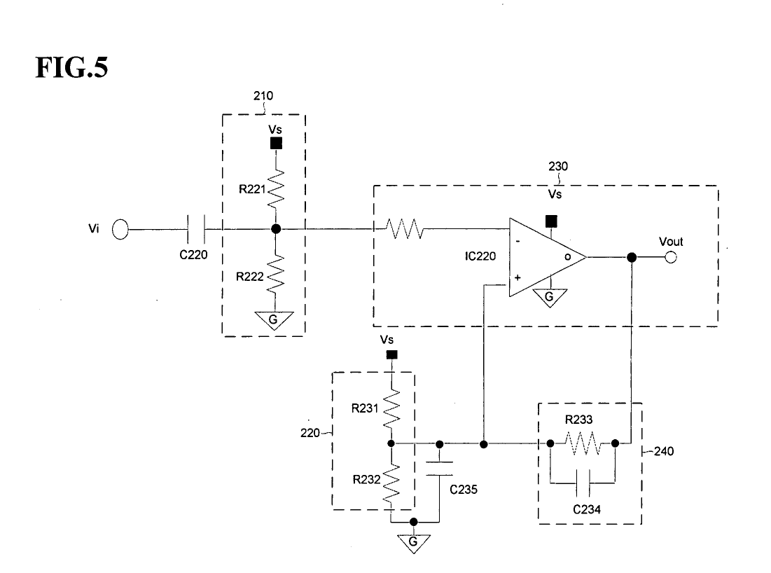

FIG. 5 shows the clock signal receiving apparatus according to the exemplary embodiment of the present invention.

As shown in FIG. 5, the clock signal receiving apparatus 200 according to the exemplary embodiment of the present invention includes a first input voltage adjusting unit 210, a second input voltage adjusting unit 220, an amplifier 230, and a feedback unit 240.

The first input voltage adjusting unit 210 receives a clock signal transmitted from the clock signal generating apparatus 100 as an input signal Vi, and adjusts a voltage level of the received clock signal by using a DC bias circuit configured with two resistors R221 and R222 coupled in series between a power source Vs and a ground terminal G. The adjusted clock signal is transmitted to a first input end of the amplifier 230. The input voltage level can be changed by adjusting the size of at least one of the two resistors R221 and R222. The DC bias circuit configured with the first resistor R221 and the second resistor R222 reduces a power noise effect of the power source Vs applied to the amplifier 230 by using a bootstrap effect of a capacitor C220.

The second input voltage adjusting unit 220 divides a voltage supplied from the power source Vs by using a voltage divider, and provides the divided voltage to a second end of the amplifier 230 as an input signal. The voltage divider is configured with two resistors R231 and R232 coupled in series between the power source Vs and the ground terminal G, and a contact of the resistors R231 and R232 is coupled to the second end of the amplifier. In addition, the voltage divider may further include a capacitor C235 coupled to the resistor R232 in parallel. The input voltage level can be changed by adjusting the size of at least one of the two resistors R231 and R232.

Through the control adjustment of the first input voltage adjusting unit 210 and the second input voltage adjusting unit 220, a logic determination time in the transient period T2 among the clock signal waveform of FIG. 4 can be adjusted.

The amplifier 230 includes a first input end, a second input end, and an output end, and generates an amplified signal by using output signals of the first input voltage adjusting unit 210 and the second input voltage adjusting unit 220 as two input signals. The amplified signal Vout is provided to another circuit (not shown) at a rear end through the output end for driving the system. According to the exemplary embodiment of the present invention, the amplifier 230 may be provided as an operational amplifier, and an inverse input end and a non-inverse input end may respectively correspond to the first input end and the second input end.

The feedback unit 240 is connected between the output end of the amplifier 230 and the second input voltage adjusting unit 220, which is the second end of the amplifier 230, to eliminate noise, and provides a hysteresis characteristic to the clock signal receiving apparatus 200. Herein, the feedback unit 240 may be configured with a parallel-coupled resistor R233 and a capacitor C234, and the hysteresis characteristic can be adjusted by changing the size of the resistor R233. That is, the hysteresis characteristic of the feedback unit 240 is used for reducing a noise effect of the clock signal according to the exemplary embodiment of the present invention.

The hysteresis characteristic is generated by the resistor R233 configured for positive feedback of a differential amplifier.

When a non-inverse reference voltage is V+ and an inverse reference voltage is V−, a hysteresis value VH can be given as Equation (1) to Equation (3).

$${V}_{+} = \frac{R 231 // R 233 // C 234}{R 232 // C 235 + ( R 231 // R 233 // C 234 )} {V}_{out} \qquad ( 1 )$$

$${V}_{-} = \frac{R 232 // C 235 // R 233 // C 234}{R 231 + R 232 // C 235 // R 233 // C 234} {V}_{out} \qquad ( 2 )$$

V_{H}=V₊−V₋ (3)

In the above Equations, an inflow noise that is less than the hysteresis value V_{H} cannot generate glitch. In this case, it is understood that the hysteresis value V_{H} can be adjusted by changing the size of the resistor R233, and a time response adjustment can be achieved by changing a value of the capacitor C234.

That is, a state of the transient period T2 is adjusted by changing the size of the respective resistors configuring the voltage dividers in the first input voltage adjusting unit 210 and the second input voltage adjusting unit 220, and accordingly, the voltage level determination timing for the clock signal can be adjusted.

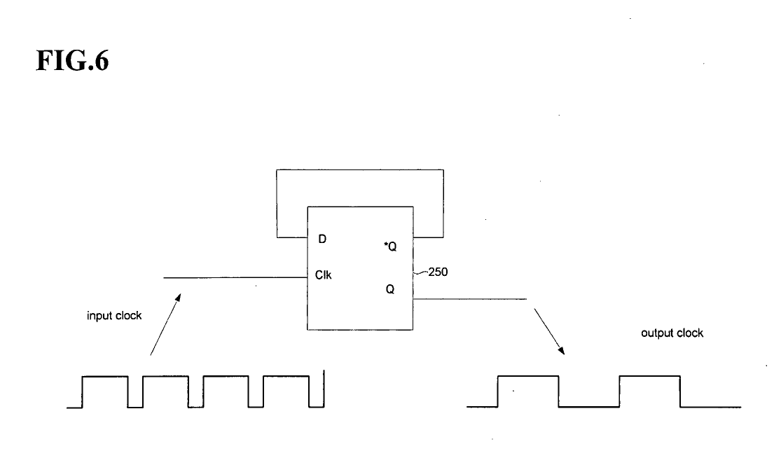

FIG. 6 shows a clock signal having its duty ratio being adjusted by using a D-flipflop. As shown in FIG. 6, when a clock signal is distorted due to noise and thus a threshold voltage for voltage level determination is increased close to a high level, clock signal determination time can be reduced. Substantially, the clock signal determination time is reduced when a duty ratio of the clock signal is less than 50%.

Therefore, according to the exemplary embodiment of the present invention, a D-flipflop 250 is additionally connected to the output end Vout of the amplifier 230 of the clock signal receiving apparatus 200 so as to obtain a clock signal having precise rising and falling times. That is, a clock signal with a duty ratio of 50% can be obtained.

According to the exemplary embodiment of the present invention, signal synchronization for high-speed signal transmission can be guaranteed in advance, transmission path delay can be compensated, and an effect of inflow noise in the receiving end can be reduced.

In addition, stability of data transmission signal synchronization can be increased by minimizing signal instability due to jitter.

In addition, a clock can be stably provided and distributed throughout the overall system.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A clock signal generating apparatus for providing a clock signal for synchronized driving of a system having a plurality of clock signal receiving apparatuses, the clock signal generating apparatus comprising:
a clock signal generator for generating a clock signal for driving the system by using an external clock signal and a feedback clock signal;
a distributor for distributing the clock signal to generate a plurality of distributed clock signals and outputting the plurality of distributed clock signals to the plurality of clock signal receiving apparatuses through a plurality of signal transmission paths; and
a plurality of delay units respectively located on the plurality of signal transmission paths, controlling phases of the plurality of distributed clock signals to generate a plurality of phase-controlled clock signals, and transmitting the plurality of phase-controlled clock signals to the plurality of clock signal receiving apparatuses,
wherein one of the plurality of delay units feeds one of the phase-controlled clock signals back to the clock signal generator.

2. The clock signal generating apparatus of claim 1, wherein a delay time of each of the clock signals, which are delayed by each of the delay units, is inversely-proportional to the length of each of the signal transmission paths.

3. The clock signal generating apparatus of claim 2, wherein the clock signal generator generates the clock signal by using a phase difference between an oscillation output of the external clock signal and an oscillation output of the feedback clock signal.

4. The clock signal generating apparatus of claim 3, wherein the clock signal generator comprises a phase locked loop.

5. The clock signal generating apparatus of claim 1, wherein the distributor comprises a plurality of zero delay buffers for generating the distributed clock signals.

6. A clock signal receiving apparatus comprising:
an amplifier for generating an amplified signal based on an input signal of a first input end and an input signal of a second input end and outputting the amplified signal to an output end;
a first input voltage adjusting unit for adjusting a voltage level of a clock signal transmitted from a clock signal generating apparatus and providing the adjusted clock signal to the first input end;
a second input voltage adjusting unit for providing a source voltage divided by a voltage divider to the second input end; and
a feedback unit connected between the output end and the second input end for eliminating noise.

7. The clock signal receiving apparatus of claim 6, wherein the feedback unit comprises parallel-coupled resistors and a capacitor, and has a hysteresis characteristic.

8. The clock signal receiving apparatus of claim 7, wherein the hysteresis characteristic of the feedback unit is adjusted by using the size of at least one of the resistors.

9. The clock signal receiving apparatus of claim 6, further comprising a D-flipflop for substantially adjusting a duty ratio of a clock signal output through the output end to 50%.
